(19) United States
(12) Patent Application Publication
(10) Pub. No.: US 2024/0353490 A1
(43) Pub. Date: Oct. 24, 2024

(54) Segmented Boundary Scan Chain Testing

(71) Applicants: Ee Mei Ooi, Bayan Lepas (MY); Prakhar Raj Gupta, Bayan Lepas (MY); Ching Sia Lim, Georgetown (MY); Ann Poh Gan, Sepang (MY); Teck Wee Patrick Tan, Tanjung Bungah (MY); Wee Sun Voon, Bayan Lepas (MY); Andrew Soon Aun Ong, Wangsa Maju (MY); Yew Siong Tew, Bayan Lepas (MY)

(72) Inventors: Ee Mei Ooi, Bayan Lepas (MY); Prakhar Raj Gupta, Bayan Lepas (MY); Ching Sia Lim, Georgetown (MY); Ann Poh Gan, Sepang (MY); Teck Wee Patrick Tan, Tanjung Bungah (MY); Wee Sun Voon, Bayan Lepas (MY); Andrew Soon Aun Ong, Wangsa Maju (MY); Yew Siong Tew, Bayan Lepas (MY)

(21) Appl. No.: 18/757,740

(22) Filed: Jun. 28, 2024

(51) Int. Cl. G01R 31/3185; G01R 31/319

(52) U.S. Cl. CPC G01R 31/318572; G01R 31/318536; G01R 31/31903

(57) ABSTRACT

Integrated circuit devices, methods, and circuitry for performing boundary scan chain testing is provided. Such an integrated circuit device may include a Joint Test Action Group (JTAG) network, a first input/output (IO) subsystem, and a second IO subsystem. The first IO subsystem includes first segmented boundary scan chain circuitry that can receive JTAG Test Data In (TDI) signals from a main JTAG test access port (TAP) of the JTAG network and use the JTAG TDI signals to perform a first boundary scan chain test. The second IO subsystem includes second segmented boundary scan chain circuitry that can receive the JTAG TDI signals from the main JTAG TAP of the JTAG network and use the JTAG TDI signals to perform a second boundary scan chain test in parallel with the first boundary scan chain test.

### BACKGROUND

This disclosure relates to test circuitry to perform segmented boundary scan chain testing of an integrated circuit device.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuit devices are found in numerous electronic devices and provide a variety of functionality. To ensure that input/output (IO) circuitry of an integrated circuit device operates properly, manufacturers or customers may perform a form of testing known as joint test action group (JTAG) boundary scan chain testing (e.g., as defined by the IEEE 1149 specification). Performing boundary scan chain testing may be very time intensive, since a boundary scan chain involves all of the IO circuits of the integrated circuit device. Over the years, techniques have been developed in an effort to increase the efficiency of boundary scan chain testing. In one example, multiple integrated circuit dies may be chained together, and boundary scan chain testing may occur in serial across the multiple integrated circuit dies. In another example, multichip products may have isolated chiplets that may be independently accessed for boundary scan testing. In another example, firmware-driven boundary scan chain testing of individual subsystems of an integrated circuit device may take place. Still, performing a boundary scan chain test using all of these previous solutions may still involve significant time and effort. Indeed, as integrated circuits grow in variety and complexity, the maintenance of the manufacturing tests grow exponentially.

### BRIEF DESCRIPTION OF THE DRAWINGS

Various aspects of this disclosure may be better understood upon reading the following detailed description and upon reference to the drawings in which:

FIG. 1 is a block diagram of an integrated circuit device with circuitry to perform a segmented JTAG boundary scan chain test of input/output (IO) subsystems of the integrated circuit device;

FIG. 2 is a block diagram of circuitry in the IO subsystems of the integrated circuit device to support the segmented JTAG boundary scan chain test;

FIG. 3 is a flowchart of a method for performing the segmented JTAG boundary scan chain test on the integrated circuit device;

FIG. 4 is a block diagram of an IO subsystem having High-Speed Serial Interface (HSSI) circuitry with circuitry to support the segmented JTAG boundary scan chain test;

FIG. 5 is a block diagram of an IO subsystem having High Voltage Input/Output (HVIO) circuitry with circuitry to support the segmented JTAG boundary scan chain test; and

FIG. 6 is a block diagram of a data processing system that may incorporate the integrated circuit.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

The circuitry of this disclosure may reduce the time and complexity involved in performing tests of input/output (IO) circuits in an integrated circuit device, such as the Joint Test Action Group (JTAG) boundary scan chain test. The IEEE 1149.1 specification defines circuitry to perform a JTAG boundary scan chain that extends across the IO circuits of the integrated circuit. Since different devices within a product family may have different varieties of IO subsystems (e.g., different types, different numbers), this leads to varying boundary chain lengths across different devices within a product family. This variation presents a significant cost challenge in testing, as the boundary scan test for each subsystem cannot be reused across these diverse devices. To account for these variations, the circuitry of this disclosure is strategically designed to enable modular JTAG boundary scan chain testing. The circuitry allows for segmented IEEE1149.1 boundary scan chain testing on an IO subsystem-by-IO subsystem basis, resulting in considerable time savings and expedited debugging. This allows for efficient testing for even cost-sensitive devices.

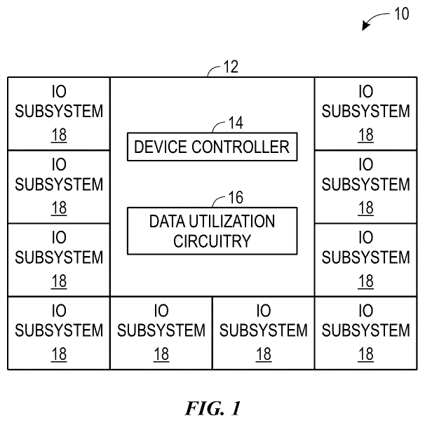

FIG. 1 illustrates a boundary scan chain test system 10 for an integrated circuit 12 that incorporates these innovations. The integrated circuit device 12 may include a processor, an application specific integrated circuit (ASIC), a programmable logic device (PLD) such as a field programmable gate array (FPGA), a memory device, a networking device, a digital signal processing (DSP) device, or any other suitable integrated circuitry. Moreover, the integrated circuit device 12 may represent a single monolithic integrated circuit or may include multiple integrated circuits in a single package or multiple packages. The integrated circuit device 12 may include a device controller 14 that controls various aspects of the operation of the integrated circuit device 12. In one specific example, the device controller 14 may be a Secure Device Manager (SDM) of a Field Programmable Gate Array (FPGA) by Altera® Corporation. The device controller 14 may enable the integrated circuit 12 to be configured or tested. Data utilization circuitry 16 may include any suitable circuitry to process data, such as a hardened microprocessor, programmable logic circuitry (e.g., programmable logic blocks such as logic array blocks (LABs) or configurable logic blocks (CLBs), programmable routing circuitry, memory, hardened digital signal processing (DSP) blocks), memory, or accelerator circuitry.

The integrated circuit device 12 may also include any suitable number and type of input/output (IO) subsystems 18. Although the IO subsystems 18 are depicted along a shoreline periphery of the integrated circuit device 12, the IO subsystems 18 may be located elsewhere in the integrated circuit device 12. For example, some of the IO subsystems 18 may be disposed within the data utilization circuitry 16 of the integrated circuit device 12 to enable certain circuits of the data utilization circuitry 16 to rapidly communicate with another integrated circuit device within the same package or outside of the package. In the example of FIG. 1, ten IO subsystems 18 are illustrated. However, different versions of the integrated circuit device 12 may include different arrangements and/or types of IO subsystems 18.

The IO subsystems 18 may take any suitable form. For instance, some of the IO subsystems 18 may take the form of a High-Speed Serial Interconnect (HSSI) IO subsystem, while other of the IO subsystems 18 may take the form of a High Voltage Input/Output (HVIO) IO subsystem. While an HVIO IO subsystem 18 may have output pins (e.g., general purpose input/output (GPIO) pins), these may not be available on an HSSI IO subsystem 18. In accordance with the IEEE1149.1 specification, the various IO subsystems 18 of the integrated circuit device 12 share a boundary scan chain that connects all of the IO subsystems 18. Because the variety in type and number of IO subsystems 18 may vary for different versions of the integrated circuit device 12, the length of the boundary scan chain connecting the IO subsystems 18 may vary accordingly. Likewise, the particular test patterns that are applied across the boundary scan chain may also vary depending on the particular arrangement of the IO subsystems 18 in each version of the integrated circuit device 12.

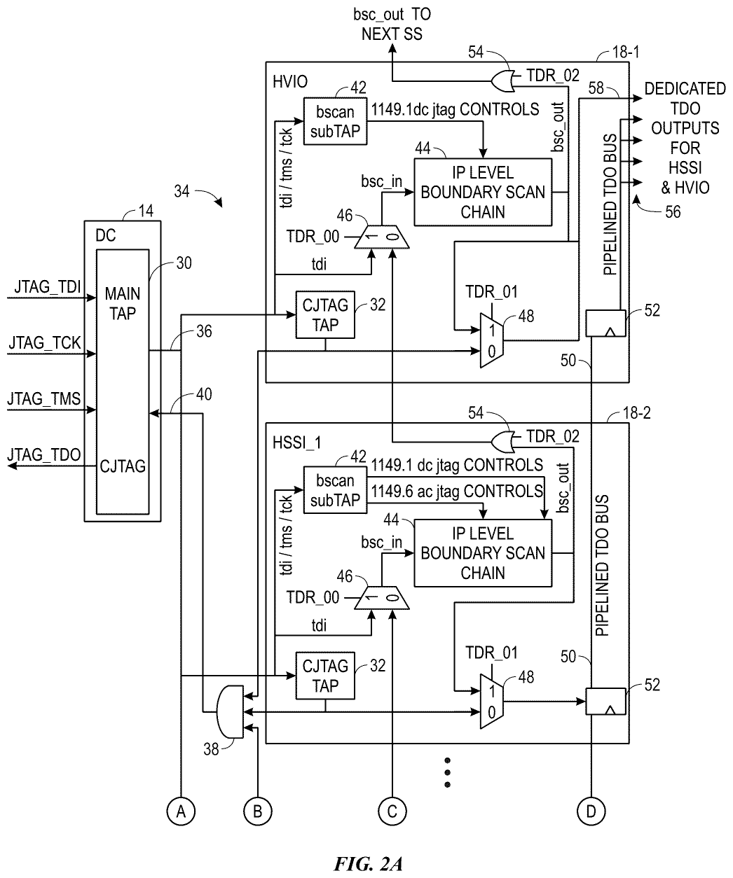

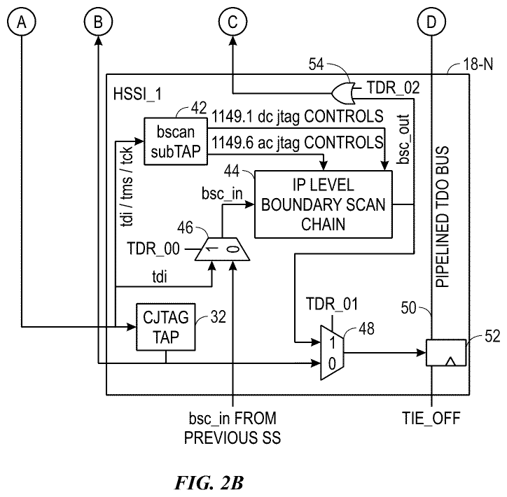

Accordingly, this disclosure presents a modular approach to performing a boundary scan chain test of the IO subsystems 18 on a subsystem-by-subsystem basis. As shown in FIG. 2, this modular approach may extend a JTAG (e.g., compact JTAG (CJTAG)) architecture. For example, a main test access port (TAP) 30 (e.g., a JTAG main TAP, a CJTAG main TAP) may receive JTAG test signals, such as Test Data In (TDI) signals, Test Clock (TCK) signals, and Test Mode Select (TMS) signals. These signals may be used to perform a variety of tests on the IO subsystems 18, in addition to boundary scan chain testing. The IO subsystems 18 are illustrated as an HVIO IO subsystem 18-1, an HSSI IO subsystem 18-2, and some number N of other HSSI subsystems 18 down to HSSI subsystems 18-N. The results of JTAG testing other than boundary scan chain testing may be output by the main TAP 30 as JTAG Test Data Out (TDO).

The main TAP 30 may represent any suitable circuitry (e.g., combinational logic circuitry, finite state machine (FSM) circuitry, a microprocessor executing instructions (e.g., software, firmware) stored in a memory device) that may receive the JTAG test signals, interpret them, and provide them to an appropriate local JTAG (e.g., CJTAG) test access port (TAP) 32 on the respective IO subsystems 18 via a JTAG network 34. The JTAG network 34 may carry input test signals on input wires 36. The JTAG network 34 may include an AND gate 38 to retrieve return signals 40 into the main TAP 30. The input test signals may be broadcast across the JTAG network 34 and received by all IO subsystems 18 or there may be selectable subnetworks of the JTAG network 34 that may route different input test signals to different groups IO subsystems 18 or single IO subsystems 18.

In addition to the local JTAG TAPs 32, the IO subsystems 18 may also include local boundary scan chain sub test access ports (bscan subTAPs) 42. The bscan subTAPs 42 may also represent any suitable circuitry (e.g., combinational logic circuitry, finite state machine (FSM) circuitry, a microprocessor executing instructions (e.g., software, firmware) stored in a memory device) that may receive boundary scan JTAG test signals (e.g., TDI, TMS, TCK), interpret them, and provide control signals (e.g., IEEE1149.1 JTAG control signals, IEEE1149.6 JTAG control signals) to an intellectual property (IP) segment level boundary scan chain 44. For example, input test signals that are broadcast over the JTAG network 34 to multiple IO subsystems 18, as shown in FIG. 2, may include addresses or instructions that are interpretable by the bscan subTAPs 42 and therefore different instructions from the input test signals may be selectively applied to particular types of IO subsystems 18.

A multiplexer 46 may select either a boundary scan output signal from a previous IO subsystem 18 or the TDI signals from the main TAP 30. A Test Data Register (TDR) (e.g., a first TDR bit shown here as TDR_00) may be programmed to provide a selection signal to the multiplexer 46. Based on the control signals from the bscan subTAP 42 and the TDI signals (entering as boundary scan input signals bsc_in), the IP segment level boundary scan chain 44 outputs a test data out (TDO) signal for the boundary scan chain of that IO subsystem 18. The TDO may be provided to a multiplexer 48 that may select between the TDO and an output of the local JTAG TAP 32 (e.g., for use in other JTAG testing other than boundary scan chain testing). Another TDR or another bit of the same TDR (e.g., a second TDR bit shown here as TDR_01) may provide a selection signal to the multiplexer 48.

Before continuing, in FIG. 2, it may be noted that the IO subsystem 18-1 is an HVIO subsystem, whereas the other IO subsystems 18-2 through 18-N are HSSI subsystems. The HVIO IO subsystem 18-1 has accessible IO pins, whereas the HSSI IO subsystems 18-2 through 18-N do not. Thus, the TDO signals from the HSSI IO subsystems 18-2 through 18-N may be provided to a pipelined TDO bus 50 supported by registers 52. The pipelined TDO bus 50 may have multiple channels. For example, there may be at least as many channels (e.g., wires, lanes) as IO subsystems 18 that lack accessible output pins (e.g., at least as many channels as HSSI IO subsystems 18). In such examples, each IO subsystem 18-2 through 18-N may use a separate channel of the pipelined TDO bus 50. If the pipelined TDO bus 50 is not used, the TDO may be provided over the full boundary scan chain as a boundary scan output signal (bsc_out) through a logic gate 54 (e.g., an OR gate where a signal-blocking input is 1 or an AND gate where a signal-blocking input is 0) having an input connected to another signal from the same or another TDR (e.g., a third TDR bit shown here as TDR_02).

The pipelined TDO bus 50 may traverse the various IO subsystems 18 that lack accessible output pins (e.g., the HSSI IO subsystems 18-N through 18-2) until reaching an IO subsystem 18 that has accessible output pins (e.g., the HVIO IO subsystem 18-1). A set of output pins 56 (e.g., general purpose input/output (GPIO) pins) of the IO subsystem 18 that has accessible output pins (e.g., the HVIO IO subsystem 18-1) may respectively provide the different TDO signals from IO subsystems 18 that lack accessible output pins (e.g., the HSSI IO subsystems 18-N through 18-2). For example, the set of output pins 56 of the IO subsystem 18-1 may include a first output pin that provides the TDO signals from the IP segment level boundary scan chain 44 of the IO subsystem 18-N, a second output pin that provides the TDO signals from the IP segment level boundary scan chain 44 of the IO subsystem 18-1, and so forth. Since the IO subsystem 18 that has accessible output pins (e.g., the HVIO IO subsystem 18-1) has access to the set of output pins 56 directly, the TDO from that IO subsystem 18 may avoid entering the pipelined TDO bus 50. Instead, for example, the TDO from the IO subsystem 18-1 may pass from its multiplexer 48 directly to a dedicated output pin 58 (e.g., VIEWPIN) of the set of output pins 56.

Although FIG. 2 illustrates one set of HSSI IO subsystems 18-2 through 18-N and one HVIO IO subsystem 18-1, there may be a variety of different types and different numbers of IO subsystems 18. Indeed, there may be multiple sets of IO subsystems 18 that share a respective pipelined TDO bus 50. In other words, there may be a first set of IO subsystems 18 that share a first pipelined TDO bus 50 that terminates at a first IO subsystem 18 that has accessible output pins and a second set of IO subsystems 18 that share a second pipelined TDO bus 50 that terminates at a second IO subsystem 18 that has accessible output pins. In some cases, a set of IO subsystems 18 may be a single IO subsystem 18 that lacks accessible output pins that uses one (unshared) pipelined TDO bus 50. In any event, because individual IO subsystems 18 may be tested independently, in a segmented fashion, boundary scan chain testing may take place in parallel, saving a significant amount of testing time. In high-volume manufacturing (HVM), this may provide a substantial savings in time and resources. What is more, because individual IO subsystems 18 may be tested independently, in a segmented fashion, a test pattern developed for one type of IO subsystem 18 may be reused for other IO subsystems 18 of the same type. This may substantially reduce the resources involved in developing test patterns, particularly for different product versions with widely varying arrangements (e.g., type, number, relative position) of IO subsystems 18.

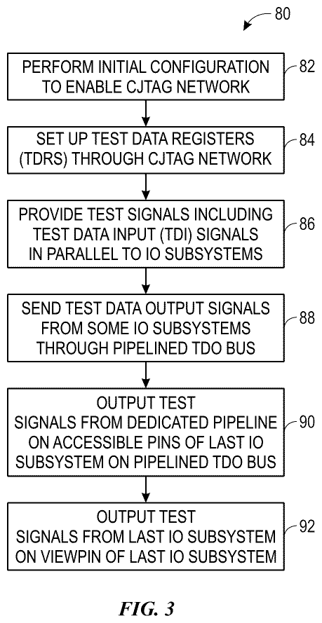

A flowchart 80 of a method for performing JTAG boundary scan chain testing using this system appears in FIG. 3. An initial configuration may be performed via the JTAG main TAP 30 of the device controller 14 to enable the use of the JTAG network 34 (e.g., CJTAG network) (block 82). Once the JTAG network 34 is initialized, the TDRs may be programmed through the JTAG network 34 (e.g., CJTAG network) (block 84). For example, the respective TDRs associated with the respective IO subsystems may be set to route the TDI from the JTAG network into the IP segment level boundary scan chain 44 (e.g., TDR_00 set to 1), route the TDO output by the IP segment level boundary scan chain 44 to the pipelined TDO bus 50 or the dedicated output pin 58 (e.g., TDR_01 set to 1), and block the full-chip boundary scan chain output signal (bsc_out) from being passed to another IO subsystem 18 (e.g., TDR_02 set to 1).

Test signals from the main TAP 30, including the TDI signals, may be provided to the IO subsystems in parallel (block 86). Based on the test signals, the IO subsystems 18 may perform boundary scan chain testing that produces output TDO signals. For IO subsystems 18 that lack accessible output pins (e.g., the HSSI IO subsystems 18-N through 18-2), the TDO signals may be sent over the pipelined TDO bus 50 (block 88) and output on a dedicated pin of an IO subsystem 18 that has accessible output pins (e.g., the HVIO IO subsystem 18-1) (block 90). For IO subsystems 18 that have accessible output pins (e.g., the HVIO IO subsystem 18-1), the TDO signals may be sent to a dedicated pin (e.g., VIEWPIN) of the same IO subsystem 18 (block 92).

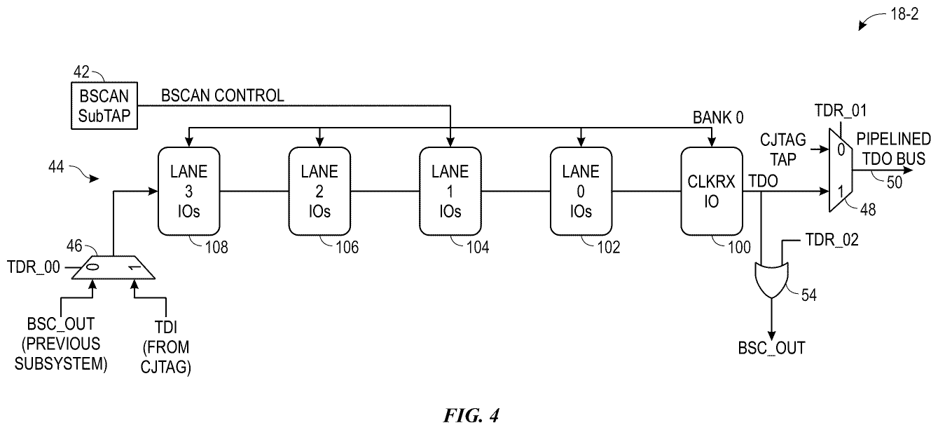

FIG. 4 illustrates a view of an HSSI IO subsystem 18 (e.g., the IO subsystem 18-2). As shown, while performing a boundary scan chain test, the bscan subTAP 42 provides control signals, shown here as BSCAN Control and representing any suitable IEEE1149.1 or IEEE1149.6 control signals. The TDR_00 register value is set to 1, so the multiplexer 46 routes the TDI signal from the CJTAG network 34 to the IP level segment boundary scan chain 44. Here, the IP level segment boundary scan chain 44 is shown to include a clock receiver IO 100 and several data lane IOs include Lane 0 IOs 102, Lane 1 IOs 104, Lane 2 IOs 106, and Lane 3 IOs 108. The TDR_02 register value is set to 1, so the logic gate 54 blocks the resulting TDO signals from the IP level segment boundary scan chain 44 from exiting as a boundary scan chain output signal BSC_OUT that would travel to the IP level segment boundary scan chain 44 of an adjacent IO subsystem 18. Moreover, the TDR_01 register value is set to 1, so the multiplexer 48 routes the TDO signals to the pipelined TDO bus 50.

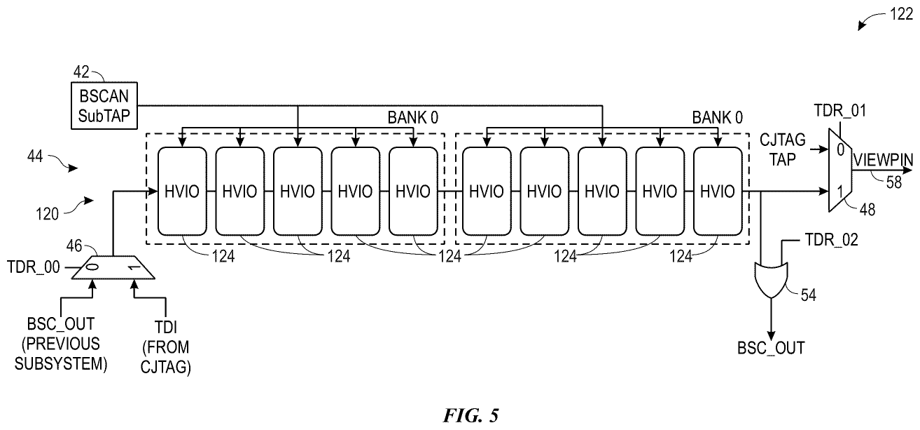

FIG. 5 illustrates a view of an HVIO IO subsystem 18 (e.g., the IO subsystem 18-1). As shown, while performing a boundary scan chain test, the bscan subTAP 42 provides control signals, shown here as BSCAN Control and representing any suitable IEEE1149.1 control signals. The TDR_00 register value is set to 1, so the multiplexer 46 routes the TDI signal from the CJTAG network 34 to the IP level segment boundary scan chain 44. In this example, the IP level segment boundary scan chain 44 includes two banks of HVIO circuits, a first bank 120 (e.g., Bank 0) and a second bank 122 (e.g., Bank 1). The first bank 120 and the second bank 122 hold a number of IO circuits 124. The TDR_02 register value is set to 1, so the logic gate 54 blocks the resulting TDO signals from the IP level segment boundary scan chain 44 from exiting as a boundary scan chain output signal BSC_OUT that would travel to the IP level segment boundary scan chain 44 of an adjacent IO subsystem 18. Moreover, the TDR_01 register value is set to 1, so the multiplexer 48 routes the TDO signals to the dedicated output pin 58 (e.g., VIEWPIN).

To rapidly test the We utilize full-chip TDI in SDM to interrupt and control the full-chip boundary scan chain within a subsystem. The local TDO is used through viewpin to unload the boundary scan chain data. As depicted in FIG. 4 (left), the purple color routing represents the original full-chip boundary scan routing. We have added red color multiplexers to disrupt the boundary scan chain routing and intercept it with the TDI from SDM and TDO to viewpin, as shown in FIG. 4 (right). The control of the red multiplexer is achieved through Test Data Register (TDR). To prevent any unintended toggling to the subsequent subsystem, we have added a safety gating mechanism (represented by the red AND gate in FIG. 4 right) on the output of the boundary scan. This gating is controlled by the JTAG TDR, which can be programmed with the appropriate values.

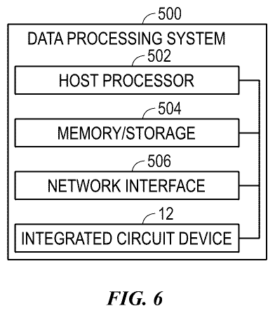

The test circuitry of this disclosure may be implemented on any suitable integrated circuit system 12, which may be a component included in a data processing system, such as a data processing system 500, shown in FIG. 6. The data processing system 500 may include the integrated circuit system 12 (e.g., a programmable logic device), a host processor 502, memory and/or storage circuitry 504, and a network interface 506. The data processing system 500 may include more or fewer components (e.g., electronic display, user interface structures, application specific integrated circuits (ASICs)). Moreover, any of the circuit components depicted in FIG. 6 may include the integrated circuit system 12 with the programmable routing bridge 84. The host processor 502 may include any of the foregoing processors that may manage a data processing request for the data processing system 500 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 504 may include random access memory (RAM), read-only memory (ROM), one or more hard drives, flash memory, or the like. The memory and/or storage circuitry 504 may hold data to be processed by the data processing system 500. In some cases, the memory and/or storage circuitry 504 may also store configuration programs (e.g., bitstreams, mapping function) for programming the integrated circuit system 12. The network interface 506 may allow the data processing system 500 to communicate with other electronic devices. The data processing system 500 may include several different packages or may be contained within a single package on a single package substrate. For example, components of the data processing system 500 may be located on several different packages at one location (e.g., a data center) or multiple locations. For instance, components of the data processing system 500 may be located in separate geographic locations or areas, such as cities, states, or countries.

The data processing system 500 may be part of a data center that processes a variety of different requests. For instance, the data processing system 500 may receive a data processing request via the network interface 506 to perform encryption, decryption, machine learning, video processing, voice recognition, image recognition, data compression, database search ranking, bioinformatics, network security pattern identification, spatial navigation, digital signal processing, or other specialized tasks.

The techniques and methods described herein may be applied with other types of integrated circuit systems. For example, the boundary scan chain testing system of this disclosure may be used with central processing units (CPUs), graphics cards, memory devices, hard drives, or other components.

While the embodiments set forth in the present disclosure may be susceptible to various modifications and alternative forms, specific embodiments have been shown by way of example in the drawings and have been described in detail herein. However, the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112 (f). However, for any claims containing elements designated in any other manner, it is intended that such elements are not to be interpreted under 35 U.S.C. 112 (f).

### Example Embodiments

EXAMPLE EMBODIMENT 1. An integrated circuit device comprising:
a Joint Test Action Group (JTAG) network;
a first input/output (IO) subsystem comprising first segmented boundary scan chain circuitry configurable to receive JTAG Test Data In (TDI) signals from a main JTAG test access port (TAP) of the JTAG network and use the JTAG TDI signals to perform a first boundary scan chain test of the first segmented boundary scan chain circuitry; and
a second IO subsystem comprising second segmented boundary scan chain circuitry configurable to receive the JTAG TDI signals from the main JTAG TAP of the JTAG network and use the JTAG TDI signals to perform a second boundary scan chain test of the second segmented boundary scan chain circuitry in parallel with the first boundary scan chain test.

EXAMPLE EMBODIMENT 2. The integrated circuit device of example embodiment 1, wherein the first IO subsystem is configurable to generate first JTAG Test Data Out (TDO) signals and send the first JTAG TDO signals to the second IO subsystem to be output on a first one or more output pins of the second IO subsystem.

EXAMPLE EMBODIMENT 3. The integrated circuit device of example embodiment 2, wherein the first IO subsystem comprises a first portion of a bus and the second IO subsystem comprises a second portion of the bus, wherein the bus is configurable to carry the first JTAG TDO signals from the first IO subsystem to the second IO subsystem.

EXAMPLE EMBODIMENT 4. The integrated circuit device of example embodiment 2, wherein the first IO subsystem comprises High Speed Serial Interconnect (HSSI) circuitry and the second IO subsystem comprises High Voltage Input/Output (HVIO) circuitry.

EXAMPLE EMBODIMENT 5. The integrated circuit device of example embodiment 2, wherein the second IO subsystem is configurable to generate second JTAG TDO signals and output the second JTAG TDO signals to the second IO subsystem on a second one or more output pins of the second IO subsystem.

EXAMPLE EMBODIMENT 6. The integrated circuit device of example embodiment 5, wherein the second one or more output pins of the second IO subsystem comprises a pin designated a VIEWPIN.

EXAMPLE EMBODIMENT 7. The integrated circuit device of example embodiment 1, wherein the second IO subsystem comprises a first multiplexer configurable to select, as an input to the second segmented boundary scan chain circuitry, between the JTAG TDI signals from the main JTAG TAP of the JTAG network and JTAG Test Data Out (TDO) signals from the first IO subsystem.

EXAMPLE EMBODIMENT 8. The integrated circuit device of example embodiment 7, wherein the first multiplexer is configurable based on a JTAG Test Data Register (TDR) value.

EXAMPLE EMBODIMENT 9. A method comprising:
performing an initial configuration to enable a Joint Test Action Group (JTAG) network of an integrated circuit device;
programming one or more JTAG Test Data Registers (TDRs) through the JTAG network;
broadcasting over the JTAG network, from a main JTAG Test Access Port (TAP) of the integrated circuit device, boundary scan chain JTAG Test Data Input (TDI) signals to a plurality of input/output (IO) subsystems of the integrated circuit device; and
performing boundary scan chain testing in parallel across the plurality of IO subsystems using the boundary scan chain JTAG TDI signals.

EXAMPLE EMBODIMENT 10. The method of example embodiment 9, comprising outputting first JTAG Test Data Out (TDO) signals generated by the boundary scan chain testing from a first IO subsystem of the plurality of subsystems onto a pipelined bus.

EXAMPLE EMBODIMENT 11. The method of example embodiment 10, comprising outputting the first JTAG TDO signals from the pipelined bus onto a first output pin of a second IO subsystem of the plurality of subsystem.

EXAMPLE EMBODIMENT 12. The method of example embodiment 11, comprising outputting second JTAG TDO signals generated by the boundary scan chain testing from the second IO subsystem onto a second output pin of the second IO subsystem.

EXAMPLE EMBODIMENT 13. An integrated circuit device comprising a plurality of input/output (IO) subsystems respectively comprising:
segmented boundary scan chain circuitry; and
a first multiplexer configurable to select, as an input to the segmented boundary scan chain circuitry:
in a first state, Joint Test Action Group (JTAG) Test Data In (TDI) signals broadcast by a main JTAG test access port; and
in a second state, JTAG Test Data Out (TDO) signals from another of the plurality of IO subsystems.

EXAMPLE EMBODIMENT 14. The integrated circuit device of example embodiment 13, wherein the first multiplexer is configurable based on a first JTAG Test Data Register (TDR) value.

EXAMPLE EMBODIMENT 15. The integrated circuit device of example embodiment 13, wherein a first IO subsystem of the plurality of IO subsystems comprises a portion of a pipelined TDO bus configurable to carry JTAG TDO signals output by the segmented boundary scan chain circuitry of the first IO subsystem to an output pin of a second IO subsystem of the plurality of input/output (IO) subsystems.

EXAMPLE EMBODIMENT 16. The integrated circuit device of example embodiment 15, wherein the first IO subsystem comprises High Speed Serial Interconnect (HSSI) circuitry and the second IO subsystem comprises High Voltage Input/Output (HVIO) circuitry.

EXAMPLE EMBODIMENT 17. The integrated circuit device of example embodiment 16, wherein the second IO subsystem comprises a dedicated output pin, wherein the dedicated output pin is configurable to output JTAG TDO signals output by the segmented boundary scan chain circuitry of the second IO subsystem.

EXAMPLE EMBODIMENT 18. The integrated circuit device of example embodiment 17, wherein the dedicated output pin comprises a pin designated as VIEWPIN.

EXAMPLE EMBODIMENT 19. The integrated circuit device of example embodiment 13, wherein the first IO subsystem comprises:
a second multiplexer configurable to select, as an input to the portion of the pipelined TDO bus:
in a first state, the JTAG TDO signals output by the segmented boundary scan chain circuitry of the first IO subsystem; and
in a second state, signals output by a local JTAG test access port (TAP).

EXAMPLE EMBODIMENT 20. The integrated circuit device of example embodiment 13, wherein the plurality of IO subsystems respectively comprises a logic gate that is register-configurable to block JTAG TDO signals output by the segmented boundary scan chain circuitry.

What is claimed is:

1. An integrated circuit device comprising:
a Joint Test Action Group (JTAG) network;
a first input/output (IO) subsystem comprising first segmented boundary scan chain circuitry configurable to receive JTAG Test Data In (TDI) signals from a main JTAG test access port (TAP) of the JTAG network and use the JTAG TDI signals to perform a first boundary scan chain test of the first segmented boundary scan chain circuitry; and
a second IO subsystem comprising second segmented boundary scan chain circuitry configurable to receive the JTAG TDI signals from the main JTAG TAP of the JTAG network and use the JTAG TDI signals to perform a second boundary scan chain test of the second segmented boundary scan chain circuitry in parallel with the first boundary scan chain test.

2. The integrated circuit device of claim 1, wherein the first IO subsystem is configurable to generate first JTAG Test Data Out (TDO) signals and send the first JTAG TDO signals to the second IO subsystem to be output on a first one or more output pins of the second IO subsystem.

3. The integrated circuit device of claim 2, wherein the first IO subsystem comprises a first portion of a bus and the second IO subsystem comprises a second portion of the bus, wherein the bus is configurable to carry the first JTAG TDO signals from the first IO subsystem to the second IO subsystem.

4. The integrated circuit device of claim 2, wherein the first IO subsystem comprises High Speed Serial Interconnect (HSSI) circuitry and the second IO subsystem comprises High Voltage Input/Output (HVIO) circuitry.

5. The integrated circuit device of claim 2, wherein the second IO subsystem is configurable to generate second JTAG TDO signals and output the second JTAG TDO signals to the second IO subsystem on a second one or more output pins of the second IO subsystem.

6. The integrated circuit device of claim 5, wherein the second one or more output pins of the second IO subsystem comprises a pin designated a VIEWPIN.

7. The integrated circuit device of claim 1, wherein the second IO subsystem comprises a first multiplexer configurable to select, as an input to the second segmented boundary scan chain circuitry, between the JTAG TDI signals from the main JTAG TAP of the JTAG network and JTAG Test Data Out (TDO) signals from the first IO subsystem.

8. The integrated circuit device of claim 7, wherein the first multiplexer is configurable based on a JTAG Test Data Register (TDR) value.

9. A method comprising:
performing an initial configuration to enable a Joint Test Action Group (JTAG) network of an integrated circuit device;
programming one or more JTAG Test Data Registers (TDRs) through the JTAG network;
broadcasting over the JTAG network, from a main JTAG Test Access Port (TAP) of the integrated circuit device, boundary scan chain JTAG Test Data Input (TDI) signals to a plurality of input/output (IO) subsystems of the integrated circuit device; and
performing boundary scan chain testing in parallel across the plurality of IO subsystems using the boundary scan chain JTAG TDI signals.

10. The method of claim 9, comprising outputting first JTAG Test Data Out (TDO) signals generated by the boundary scan chain testing from a first IO subsystem of the plurality of subsystems onto a pipelined bus.

11. The method of claim 10, comprising outputting the first JTAG TDO signals from the pipelined bus onto a first output pin of a second IO subsystem of the plurality of subsystem.

12. The method of claim 11, comprising outputting second JTAG TDO signals generated by the boundary scan chain testing from the second IO subsystem onto a second output pin of the second IO subsystem.

13. An integrated circuit device comprising a plurality of input/output (IO) subsystems respectively comprising:
segmented boundary scan chain circuitry; and
a first multiplexer configurable to select, as an input to the segmented boundary scan chain circuitry:
in a first state, Joint Test Action Group (JTAG) Test Data In (TDI) signals broadcast by a main JTAG test access port; and
in a second state, JTAG Test Data Out (TDO) signals from another of the plurality of IO subsystems.

14. The integrated circuit device of claim 13, wherein the first multiplexer is configurable based on a first JTAG Test Data Register (TDR) value.

15. The integrated circuit device of claim 13, wherein a first IO subsystem of the plurality of IO subsystems comprises a portion of a pipelined TDO bus configurable to carry JTAG TDO signals output by the segmented boundary scan chain circuitry of the first IO subsystem to an output pin of a second IO subsystem of the plurality of input/output (IO) subsystems.

16. The integrated circuit device of claim 15, wherein the first IO subsystem comprises High Speed Serial Interconnect (HSSI) circuitry and the second IO subsystem comprises High Voltage Input/Output (HVIO) circuitry.

17. The integrated circuit device of claim 16, wherein the second IO subsystem comprises a dedicated output pin, wherein the dedicated output pin is configurable to output JTAG TDO signals output by the segmented boundary scan chain circuitry of the second IO subsystem.

18. The integrated circuit device of claim 17, wherein the dedicated output pin comprises a pin designated as VIEWPIN.

19. The integrated circuit device of claim 13, wherein the first IO subsystem comprises:
a second multiplexer configurable to select, as an input to the portion of the pipelined TDO bus:
in a first state, the JTAG TDO signals output by the segmented boundary scan chain circuitry of the first IO subsystem; and
in a second state, signals output by a local JTAG test access port (TAP).

20. The integrated circuit device of claim 13, wherein the plurality of IO subsystems respectively comprises a logic gate that is register-configurable to block JTAG TDO signals output by the segmented boundary scan chain circuitry.
